(19) United States
(12) Patent Application Publication
(10) Pub. No.: US 2006/0043558 A1
(43) Pub. Date: Mar. 2, 2006

(54) Stacked integrated circuit cascade signaling system and method

(75) Inventors: James W. Cady, Austin, TX (US); Russell Rapport, Austin, TX (US); James Wilder, Austin, TX (US)

Correspondence Address: J. SCOTT DENKO;ANDREWS & KURTH LLP, 111 CONGRESS AVE, SUITE 1700, AUSTIN, TX, 78701, US

(73) Assignee: Staktek Group L.P., Austin, TX (US)

(21) Appl. No.: 10/931,828

(22) Filed: Sep. 1, 2004

(51) Int. Cl. H01L 23/02

(52) U.S. Cl. 257/686

(57) ABSTRACT

Abstract of the Disclosure

Integrated circuits (ICs) are stacked into modules that conserve PCB or other board surface area. The modules provide for lower capacitance memory signaling systems and methods for connecting stacked CSPs in a serial cascade arrangement. In one preferred embodiment, on-die terminations are used selectively to terminate a cascaded series of conductive paths. In another preferred embodiment, a form standard provides a physical form that allows many of the varying package sizes found in a broad family of CSP packages to be used to advantage while employing a standard connective flex circuitry design.

### Detailed Description of the Invention

### FIELD:

The present invention relates to signaling interconnects among stacked integrated circuits.

### BACKGROUND:

A variety of techniques are used to stack packaged integrated circuits (ICs). Some techniques require special packages, while other techniques stack conventional packages. In some techniques, flexible conductors are used to selectively interconnect packaged integrated circuits. Staktek Group L.P. has developed numerous systems for aggregating FBGA (Fine-Pitch Ball Grid Array) packages in space saving topologies.

Memory expansion is one of the many fields in which stacked module solutions provide space saving advantages. For example, the well-known DIMM (Dual In-line Memory Module) board is frequently populated with stacked modules built by Staktek Group L.P. of Austin, TX. Such modules add capacity to the board without adding sockets. A memory expansion board such as, for example, a DIMM, provides plural sites for memory IC placement (i.e., sockets) arranged along one or both major surfaces of a board and connected to an array of contacts arranged along at least one board edge. Stacking reduces interconnect length per unit of memory, and thus takes advantage of the general rule that interconnects that are less than half the spatial extent of the leading edge of a signal operate as a lumped element more than they do as a transmission line. Stacking typically increases the number of devices on a DIMM board and therefore may increase the capacitive loading from certain transmission line receivers connected to the interconnect lines. Another issue related to stacking interconnection is that some stacked signaling topologies complicate the DIMM board signal integrity and transmission line termination schemes by routing commonly-used signals in a stack using a separate conductive path traveling up the stack to each IC, or a series connection up the stack to the top IC. Board signal integrity schemes are generally developed assuming a minimal length connection from a circuit board trace to the interior terminal of the packaged IC.

At high frequencies, the length of conductive paths vertically traversing a stacked module may be greater than the critical length associated with the frequency employed. Such a relationship may suggest that stack interconnects should be analyzed as transmission lines when developing signaling schemes and when designing transmission line termination topologies.

Transmission line termination refers to strategies or systems used to cancel, mitigate, or dampen signal reflections on transmission lines. Some transmission line termination techniques also mitigate other signal integrity problems such as “ringing” oscillations and signal delays. A typical DIMM board has individual memory ICs mounted on the board immediately adjacent to the transmission line traces. With such an arrangement, the conductive path through the IC packaging contacts typically presents a lumped connection that does not cause significant reflections or behave like a transmission line. A typical DIMM transmission line topology may treat conductive paths in IC packaging as a lumped circuit element. By contrast, a DIMM board populated with stacked ICs does not have each IC mounted on the board immediately adjacent to the transmission line trace. Instead, the upper stacked ICs are above the lower stacked ICs and interconnected with means such as, for example, flexible conductors. Such interconnection may not present a lumped connection. A transmission line termination topology devised to more optimally interconnect ICs on the DIMM will treat stack conductive paths as transmission line elements.

What is needed therefore are methods and structures for stacking circuits in thermally efficient, reliable structures that perform well at higher frequencies but are not too tall, yet can be made at reasonable cost with commonly available and readily managed materials. What is also needed are methods and signaling systems that reduce interconnect lengths or loading with a favorable termination topology when employed in memory expansion boards and design.

### SUMMARY:

Integrated circuits (ICs) are stacked into modules that conserve PCB (printed circuit board) or other board surface area. Preferred embodiments of the present invention can be used to advantage with CSP (chipscale packages) of a variety of sizes and configurations. Such variety may range from larger packaged devices having a large array of many dozens of contacts to smaller packages such as, for example, die-sized packages such as DSBGA (die-sized ball grid array).

In one embodiment, a module of stacked memory CSPs has corresponding signal contacts serially connected to provide a conductive path from a first module contact to each one of corresponding signal contacts for the constituent devices. The signal contacts may express one-way or two-way signal terminals. The conductive path further connects to a second module contact, which may be connected serially to another similarly configured module. In a preferred embodiment, a series of four-high stacked CSP modules is disposed on a memory expansion board and the conductive path connecting corresponding signals between CSPs and modules is terminated at the end of the series using on-die-termination(s) in the CSPs or using other termination techniques.

Multiple numbers of CSPs may be stacked. A four-high CSP stacked module is preferred for use with the disclosed memory signaling system. For many other applications, a two-high CSP stack or module devised in accordance with this disclosure is preferred. The CSPs employed in stacked modules are preferably connected with flex circuitry. The flex circuitry may exhibit one or two or more conductive layers. In preferred embodiments, the flex circuitry as two conductive layers.

In preferred modules, the flex circuitry is partially wrapped about a form standard. A form standard provides a physical form that allows many of the varying package sizes found in the broad family of CSP packages to be used to advantage while employing a standard connective flex circuitry design. The form standard can take many configurations and may be used where flex circuitry is used to connect ICs to one another in stacked modules having two or more constituent ICs. In a preferred embodiment, the form standard will be devised of heat transference material, a metal for example, to improve thermal performance.

### BRIEF DESCRIPTION OF THE DRAWINGS:

Fig. 1 depicts a stacked IC connection topology according to a preferred embodiment.

Fig. 2 is a circuit diagram of another embodiment of the present invention.

Fig. 3 depicts a circuit topology of one embodiment with a two-high configuration.

Fig. 4 is an exploded depiction of an alternative embodiment in a two-high configuration.

Fig. 5 is an elevation view of module 10 devised in accordance with a preferred embodiment.

Fig. 6 shows a two-high module 10 devised in accordance with a preferred embodiment.

Fig. 7 is a cross-sectional view of a portion of a preferred embodiment depicting one preferred construction for flex circuitry.

Fig. 8 depicts a cross-sectional view of an alternative preferred construction in a contact area in accordance with another preferred embodiment.

Fig. 9 depicts a series of four 4-high stacked modules mounted on a memory expansion board in accordance with another embodiment.

Fig. 10 is a signal flow diagram of a DIMM card according to another embodiment.

Fig. 11 depicts a stacked IC connection topology according to another embodiment.

### DETAILED DESCRIPTION OF PREFERRED EMBODIMENTS:

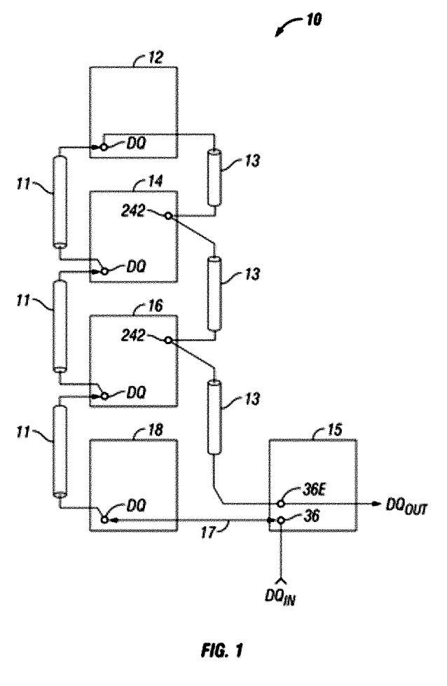

Fig. 1 depicts a stacked IC connection topology according to a preferred embodiment of the present invention. In this embodiment, a signaling topology connects memory integrated circuits in stacked module 10 according to a serial cascade connection scheme. The depicted signaling topology provides a signal path equivalent to a continuous series connection between corresponding signal contacts on a plurality of memory CSPs.

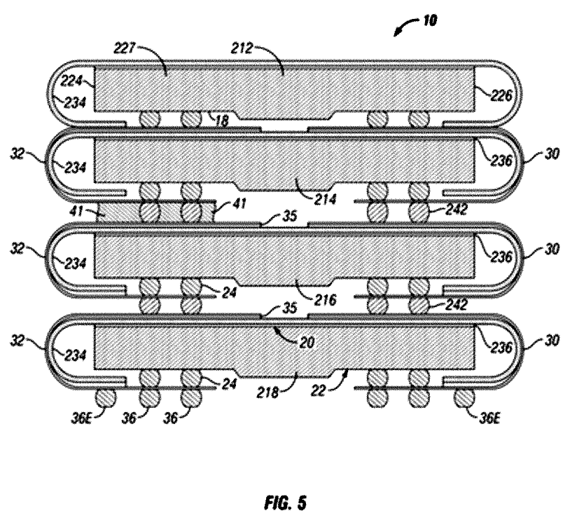

Circuit diagram representations of ballout patterns 12, 14, 16, and 18 are shown for a plurality of CSPs, which CSPs are arranged in a stacked disposition (preferably as depicted in Figures 5-8). Depicted CSP ballouts 12, 14, 16, and 18 are simplified circuit diagrams of contact arrays on a CSP package. To simplify the depiction, only a few contacts are shown. The depicted CSP ballouts 12, 14, 16, and 18 are preferably connected with flexible circuits (examples of which flex circuits are depicted in Figures 5-8). CSP ballouts 12, 14, 16, and 18 are connected according to a cascade serial connection scheme.

Fig. 1 depicts one preferred embodiment showing connections for one DQ (data queue) data signal DQ_{IN}. Data signal DQ_{IN} connects stack ballout 15 through a module contact 36, which connects module 10 to its operating environment. Module contact 36 is connected to a DQ contact of CSP ballout 18. CSP ballout 18 corresponds to the lowest stacked CSP in module 10. Preferably, connection of module contact 36 to contact DQ is made with an inter-contact connection 17 or a trace at a conductive layer of a flex circuit (as described with regard to Figures 5-8). Contact DQ is connected to corresponding contacts DQ on the other CSP ballouts in module 10 with cascade lines 11. Each cascade line 11 is connected preferably to the corresponding DQ contact at each level through an inter-flex contact as described with reference to Fig. 5. Cascade lines 11 are preferably composed of respective conductive layer connections and flex circuit traces (described with regard to Figures 5-8). Contact DQ of CSP ballout 12 is serially connected by cascade line 13 to inter-flex contact 242 associated with CSP ballout 14. Inter-flex contact 242 (preferably devised according to the scheme depicted in later-referenced Fig. 5) enables connections between the depicted CSP ballouts. The depicted inter-flex contacts 242 are connected to a no-connect (NC) contact on each of the ballouts 14 and 16. The lower cascade line 13 connects to supplemental contact 36E on module ballout pattern 15.

In other embodiments, inter-flex contact 242 instead may be provided as a supplemental inter-flex contact which provides a supplemental electrical connection between the stacked layers of module 10. Such supplemental electrical connections may provide a capability to connect any two adjacent stacked layers of module 10 with a number of conductive paths greater than the number of contacts on a particular CSP ballout. In this embodiment, contact 242 on CSP ballout 16 is connected to supplemental contact 36E, which connects module 10 to signal DQ_{OUT}. Cascade lines 11 and 13 provide a continuous conductive path from module contact 36 to supplemental module contact 36E. A circuit board trace carrying signal DQ_{OUT} may be connected to a corresponding DQ_{IN} contact on another module 10. In other embodiments, contact 36E may connect to a transmission line termination.

Fig. 1 depicts portions of cascade lines 11 and 13 as transmission line circuit elements. Conductive layer connections and flex circuit traces may in certain embodiments exhibit transmission line qualities. The nature of those qualities will vary depending on various characteristics such as the lengths of the various conductive layer connections and flex circuit traces employed, and the transition times of signals transmitted on such connections and traces. In other embodiments of the invention, the length or aggregate length of cascade lines 11 and 13 may be, however, smaller than the critical length of a transmission line at high signaling speeds which may be employed in certain systems containing the present invention. If a particular module 10 is employed with a signaling scheme having such a critical length, individual cascade lines 11 and 13 may take on the characteristics of a lumped circuit element rather than a transmission line. The described round path connection between module contact 36 and supplemental contact 36E will typically exhibit transmission line behavior. While for simplicity only one set of cascade lines 11 and 13 is shown in Fig. 1, more than one set of cascade lines is typically employed. Further, while a data signal DQ is depicted, the described connection scheme may be used with other signals that have corresponding terminals on multiple CSPs in a stack such as, for example, memory address lines and control lines.

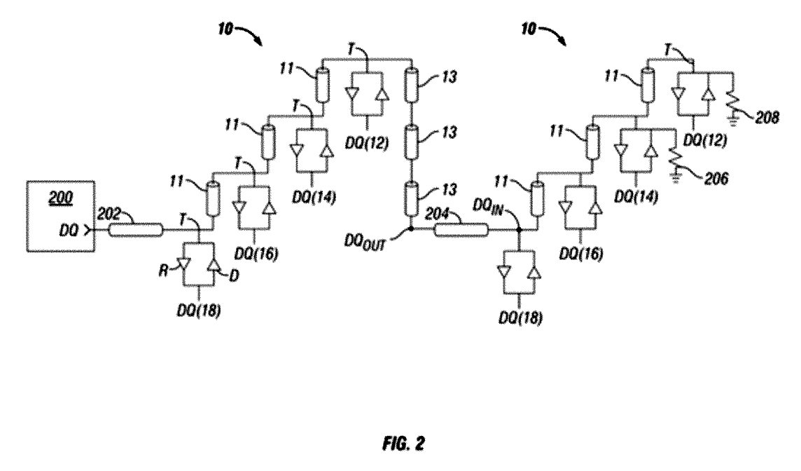

Fig. 2 is a circuit diagram of another embodiment of the present invention. A memory buffer 200 is shown connected to two consecutive modules 10 each having four memory CSPs. Memory buffer 200 may contain various logic circuitry needed to multiplex and/or buffer and/or provide control to the memory CSPs in modules 10. Fig. 2 depicts the connection of a single data signal DQ, however a memory system will have multiple data lines. Stacked memory CSPs may have data lines combined in various ways to achieve a desired capacity, memory datapath width, or other system design parameter. Further, while Fig. 2 depicts a series of two modules 10, preferred embodiments typically will have more modules 10 arranged in a series. Memory buffer 200 has bi-directional signal terminal DQ, which connects preferably on a circuit board through transmission line 202 to a module 10. A lower CSP 218 (Fig. 5) has bi-directional signal DQ(18) with a signal interface provided by receiver R and driver D connected to terminal T. In this embodiment, terminal T connects to connect trace 202 through contact DQ (“contact”, “terminal contact”) as described with reference to Fig. 1. Cascade lines 11 connect contact DQ to terminals T in series. Terminals T are associated with internal DQ signals DQ(12), DQ(14), DQ(16) and DQ(18), which signals are conveyed to and from their respective CSPs 212, 214, 216, and 218 (preferably arranged as shown in Fig. 5). The depicted circuit for the left-hand module 10 in Fig. 2 corresponds to the topology of Fig. 1. In this embodiment, the DQ_{OUT} signal terminal of the depicted left-hand module 10 is connected through transmission line 204 to the DQ_{IN} signal terminal of the depicted right-hand module 10. Transmission lines 202 and 204 together with the depicted cascade lines 11 and 13 of both depicted modules 10 form a continuous conductive path ending at the top terminal T of the depicted right-hand module 10. In this embodiment, the right-hand module 10 is not provided with cascade lines 13, but is terminated with resistors 206 and 208. The parallel combination of resistors 206 and 208 is, in this embodiment, designed to match the impedance of the various transmission lines. Resistors 206 and 208 are on-die-terminations (ODT) associated with the respective DQ terminals of CSPs 12 and 14 of the depicted right-hand module. All of the ODT of the CSPs in both modules are selectively controlled to activate resistors 206 and 208, but deactivate the ODTs at other depicted terminals T. Such ODT may be associated with the other depicted DQ terminals, but such other ODT would, in this embodiment, be operated in a deactivated state and are not shown to simplify the depiction. While two resistors, 206 and 208, are shown, other embodiments may terminate the conductive path with only one ODT. Certain chipsets have ODT that may not, in certain signaling schemes, provide low enough resistance to match the impedance of cascade lines 11. Further, while resistor 208 is shown as a single circuit element, various ODT schemes may be used that may involve multiple on-die resistors controlled with switches to achieve a matching termination and while a connection to ground is shown, various other termination schemes may be provided with the ODT such as, for example, a parallel termination connected to voltage Vddq.

The depicted cascade traces 11 and 13 will preferably present an effective matching impedance Z. Such impedance, however, will typically be influenced by the capacitive load presented at each terminal T by receiver R and driver D. To correct such an influence, the impedance Z of the depicted cascade traces 11 may be a higher impedance than that of traces 13, the higher impedance designed in a manner devised to match the equivalent impedance of combined cascade traces 11 and the capacitive load at terminal T to present a conductive path with minimal impedance discontinuity from buffer 200 to resistor 208. Such a higher impedance may be achieved by adjusting the design parameters of cascade lines 11 such as, for example, the width of conductive traces implementing cascade lines 11. Further, the width of such traces may be narrower (and thereby have higher impedance) at the middle of the trace than at the end of the trace to mitigate impedance discontinuity in situations such as, for example, when cascade lines 11 are near or above the associated critical length.

While in this embodiment a combination of ODT resistors is used to terminate the depicted conductive path, other embodiments may instead have resistor 208 mounted on a flex circuit within the module 10 or mounted to the circuit board of the module 10’s operating environment and connected by additional cascade traces 13 (not shown in this Figure). Further, the serially connected and stacked topology described with regard to Figs. 1 and 2 will preferably be driven with current mode drivers. However, this is not limiting and voltage mode drivers may be employed in some embodiments of the invention.

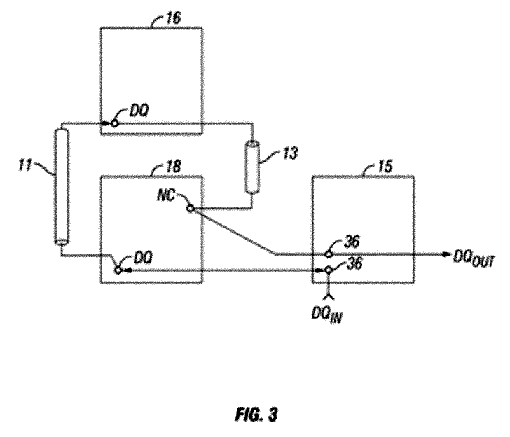

Fig. 3 depicts a circuit topology of a embodiment of the invention with a two-high configuration. The depicted topology presents a single conductive path for signal DQ_{IN} through a module contact 36 on module ballout pattern 15, connected to a selected DQ contact on CSP ballout 18 and next through cascade line 11 to a DQ contact on CSP ballout pattern 16. Cascade line 13 connects to contact NC on CSP ballout pattern 18 and to module contact 36. The connections between ballout patterns will be further described with regard to below-referenced Figures. In alternative embodiments, cascade line 13 may not be connected to an unused contact NC but instead may connect to a supplemental module contact on module ballout pattern 15.

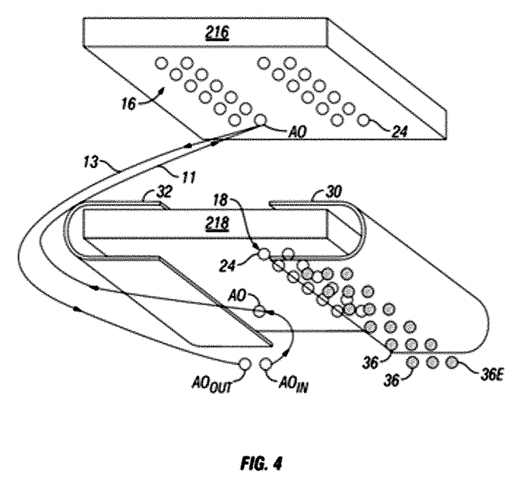

Fig. 4 is an exploded depiction of an alternative embodiment of the invention in a two-high configuration. In this embodiment, CSPs 216 and 218 are connected by conductive traces on flex circuits 30 and 32. CSPs 216 and 218 have contacts 24 arrayed on their bottom major surface. Contacts 24 comprise ballout patterns 16 and 18 such as those described with reference to Figs. 1 and 3. Module contacts 36 and 36E are connected to flex circuits 30 and 32 opposite to contacts 24 of CSP 218. Module contacts 36 and 36E comprise a module ballout pattern 15 such as those described with reference to Figs. 1 and 3. Only a few contacts are shown on one side of CSP 218 to simplify the view and some module contacts 36 and 36E are shaded to improve clarity of view. In this depiction, a serial cascade connection is shown for an address signal A0. Data signals and control signals may be similarly connected. Signal A0 is shown as a curved line to contacts to which it is connected. Signal A0 will typically travel on a circuit board trace which connects to the module contact referenced A0_{IN}, which module contact connects to a corresponding contact 24 referenced A0 on CSP 218. Cascade line 11 is implemented in this embodiment as a conductive trace in flex 32 which conveys signal A0 through flex 32 to a corresponding contact 24 referenced A0 on CSP 216. Cascade line 13 conveys signal A0 to the module contact referenced A0_{OUT}. From module contact A0_{OUT}, signal A0 may connect to another similar module 10 and thereby serially connect corresponding terminal contacts 24 through a series of high density circuit modules 10. At the final module in the series, the conductive path, formed by cascade lines 11 and 13 and conductive traces connecting adjacent pairs of modules, is terminated with a transmission line termination (not shown in this Figure), which may be an ODT or may be a resistor mounted on the circuit board or on one of the flex circuits.

Fig. 5 is an elevation view of a module 10 devised in accordance with a preferred embodiment of the present invention. The depicted module 10 is comprised of four CSPs: level four CSP 212, level three CSP 214, level two CSP 216, and level one CSP 218. Each of the CSPs has an upper surface 20 and a lower surface 22 and opposite lateral edges 224 and 226 and typically include at least one integrated circuit surrounded by a plastic body 227. The body need not be plastic, but a large majority of packages in CSP technologies are plastic. Those of skill will realize that the present invention may be devised to create modules with different size CSPs and that the constituent CSPs may be of different types within the same module 10. For example, one of the constituent CSPs may be a typical CSP having lateral edges 224 and 226 that have an appreciable height to present a "side" while other constituent CSPs of the same module 10 may be devised in packages that have lateral edges 224 and 226 that are more in the character of an edge rather than a side having appreciable height.

The invention is used with CSP packages of a variety of types and configurations such as, for example, those that are die-sized, as well those that are near chip-scale as well as the variety of ball grid array packages known in the art. It may also be used with those CSP-like packages that exhibit bare die connectives on one major surface. Thus, the term “CSP” should be broadly considered in the context of this application. Collectively, these will be known herein as chip scale packaged integrated circuits (CSPs) and some preferred embodiments will be described in terms of CSPs, but the particular configurations used in the explanatory figures are not, however, to be construed as limiting.

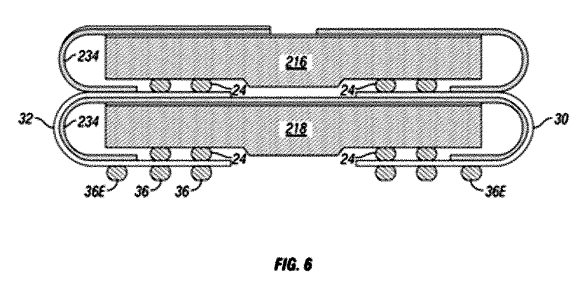

A variety of combinations of packages including leaded and CSP and other configurations of packaged ICs may be employed to advantage by the invention. For example, the elevation views of Figs. 5 and 6 are depicted with CSPs of a particular profile known to those in the art, but it should be understood that the figures are exemplary only.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 22 of a plastic casing in any of several patterns and pitches. An external portion of the connective contacts is often finished with a ball of solder. Shown in Fig. 5 are contacts 24 along lower surfaces 22 of the illustrated constituent CSPs 212, 214, 216, and 218. Contacts 24 provide connection to the integrated circuit or circuits within the respective packages. In embodiments of the present invention, module 10 may be devised to present a lower profile by stripping from the respective CSPs, the balls depicted in Fig. 5 as contacts 24 and providing a connection facility at contact 24 that results from solder paste that is applied either to the pad contact of the CSP that is typically present under or within the typical ball contacts provided on CSP devices or to the contact sites on the flex circuitry to be connected to contact 24.

In Fig. 5, iterations of flex circuits (“flex”, “flex circuits” or “flexible circuit structures”) 30 and 32 are shown connecting various constituent CSPs. Some embodiments may employ more than one flex. The entire flex circuit may be flexible or, as those of skill in the art will recognize, a PCB structure made flexible in certain areas to allow conformability in some areas and rigid in other areas for planarity along contact surfaces may be employed as an alternative flex circuit in the present invention. For example, structures known as rigid-flex may be employed. One embodiment of a such a rigid flex structure places rigid portions in and around areas where contacts 24 are attached to flex circuits 30 and 32, such rigid portions terminating before the depicted bend in each flex circuit 30 and 32.

In the depicted embodiment of module 10, form standard 234 is shown disposed adjacent to upper surface 20 of each of the CSPs. Form standard 234 may be fixed to upper surface 20 of the respective CSP with an adhesive 236 which preferably is thermally conductive. Form standard 234 may also, in alternative embodiments, merely lay on upper surface 20 or be separated from upper surface 20 by an air gap or medium such as a thermal slug or non-thermal layer. However, where form standard 234 is a thermally conductive material such as the copper that is employed in a preferred embodiment, layers or gaps interposed between form standard 234 and the respective CSP (other than thermally conductive layers such as adhesive) are not highly preferred.

Form standard 234 is, in a preferred embodiment, devised from copper to create, as shown in the depicted preferred embodiment, a mandrel that mitigates thermal accumulation while providing a standard sized form about which flex circuitry is disposed. Form standard 234 may take other shapes and forms such as for example, an angular "cap" that rests upon the respective CSP body or as another example, it may be folded to increase its cooling surface area while providing an appropriate axial form for the flex that is wrapped about a part of form standard 234. It also need not be thermally enhancing although such attributes are preferable. The form standard 234 allows the invention to be employed with CSPs of varying sizes, while articulating a single set of connective structures useable with the varying sizes of CSPs.

Portions of flex circuits 30 and 32 may be fixed to form standard 234 by adhesive 35 which is preferably a tape adhesive, but may be a liquid adhesive or may be placed in discrete locations across the package. Preferably, adhesive 35 is thermally conductive. In other embodiments, portions of flex circuits 30 and 32 may be fixed to form standard 234 by metallic bonds.

In a preferred embodiment, flex circuits 30 and 32 are multi-layer flexible circuit structures that have at least two conductive layers. Other embodiments may, however, employ flex circuitry, either as one circuit or two flex circuits, that have only a single conductive layer.

Preferably, the conductive layers are metal such as alloy 110. The use of plural conductive layers provides advantages and the creation of a distributed capacitance across module 10 intended to reduce noise or bounce effects that can, particularly at higher frequencies, degrade signal integrity, as those of skill in the art will recognize. Module 10 of Fig. 5 has plural module contacts 36 and supplemental contacts 36E (“extra contacts”, “contacts”). Connections between flex circuits are shown as being implemented with inter-flex contacts 242 which are shown as balls but may be low profile contacts constructed with pads and/or rings that are connected with solder paste applications to appropriate connections. Appropriate fills such as those indicated by conformal media 41 can provide added structural stability and coplanarity where desired. Media 41 is shown only as to CSPs 214 and 216 and only on one side to preserve clarity of view.

Fig. 6 shows a two-high module 10 devised in accordance with a preferred embodiment of the invention. Module 10 of Figs. 5 and 6 has plural module contacts 36 and supplemental module contacts 36E. In this embodiment, form standard 234 extends underneath CSP 218 in a manner devised to provide support and thermal connectivity. Other embodiments may provide a form standard that does not extend underneath CSP 218 or may span the entire lateral extent of CSP 218 to provide mechanical support and thermal conductivity. Supplemental contacts 36E are devised to provide extra input/output signal paths and connectivity for the depicted CSPs in module 10. For example, in some embodiments, supplemental contacts 36E will provide a signal path enabling the combination of more than one datapath of ‘n’ bits from respective CSPs of module 10 into a combined datapath of 2-n bits, 3-n bits, 4-n bits, or more. Supplemental contacts may also provide connectivity for signals such as chip enable signals, address lines, timing signals such as, for example, strobe signals, or various other input/output and signaling connectivity that may be required.

Extra contacts 36E are depicted as solder balls, but this is not limiting and extra contacts 36E may take other forms of chipscale contacts, such as, for example, plated bumps, solder bumps, and balls. Further, module and extra contacts 36 and 36E may be solder balls having a circumference smaller or larger than CSP contacts 24. In this embodiment, module contacts 36 and extra contacts 36E are disposed in a pattern aligned with the pattern of CSP contacts 24 of CSP 218. Extra contacts 36E are depicted in extra rows disposed in a direction toward the periphery of module 10 from module contacts 36 and CSP contacts 24. This is not limiting, however, and extra contacts 36E may be disposed toward the center of the bottom surface of CSP 218, and/or grouped within the “footprint” of CSP contacts 24 in a manner devised to lower the pitch and/or size of module contacts 36 and extra contacts 36E. Other embodiments may use a single flex circuit connecting respective pairs of CSPs and thus may provide signals that cross between respective arrays of contacts on right and left sides of the stacked CSPs. Still other embodiments may stack CSPs having peripheral arrays of contacts or having filled arrays of contacts or arrays modified by methods such as those examples found in co-pending U.S. Pat. Apps. Nos. 10/631,886 and 10/457,608.

Heat transference can be improved with use of a form standard 234 comprised of heat transference material such as a metal or preferably, copper or a copper compound or alloy to provide a significant sink for thermal energy. Such thermal enhancement of module 10 particularly presents opportunities for improvement of thermal performance where larger numbers of CSPs are aggregated in a single stacked module 10.

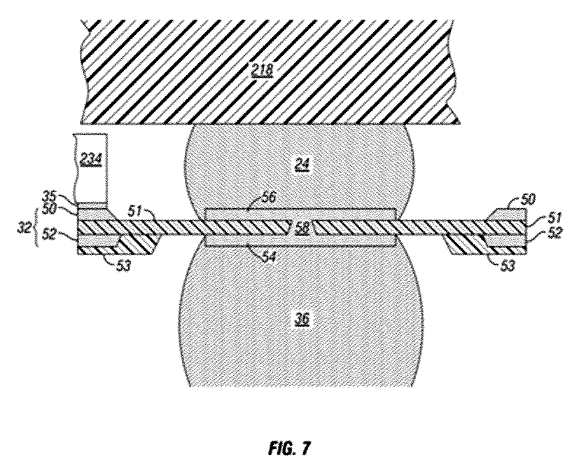

Fig. 7 is a cross-sectional view of a portion of a preferred embodiment depicting a preferred construction for flex circuitry which, in the depicted embodiment is, in particular, flex circuit 32 which includes two conductive layers 50 and 52 separated by intermediate layer 51. Preferably, the conductive layers are metal such as alloy 110.

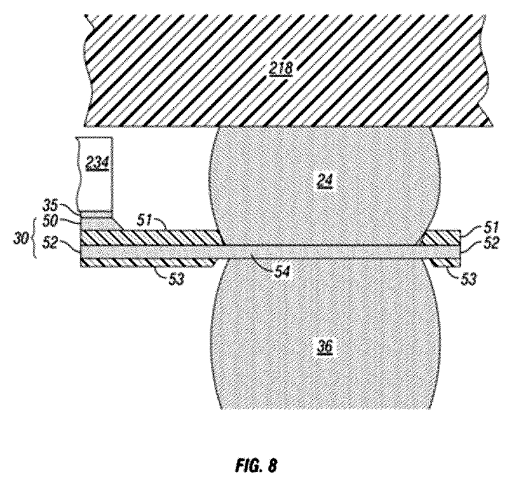

With continuing reference to Fig. 7, optional outer layer 53 is shown over conductive layer 52 and, as those of skill will recognize, other additional layers may be included in flex circuitry employed in the invention, such as a protective inner layer over conductive layer 50, for example. Flex circuits that employ only a single conductive layer such as, for example, those that employ only a layer such as conductive layer 52 may be readily employed in embodiments of the invention. The use of plural conductive layers provides, however, advantages and the creation of a distributed capacitance across module 10 intended to reduce noise or bounce effects that can, particularly at higher frequencies, degrade signal integrity, as those of skill in the art will recognize. In the depicted preferred embodiment, flex contact 54 at the level of conductive layer 52 and flex contact 56 at the level of conductive layer 50 provide contact sites to allow connection of module contact 36 and CSP contact 24 through via 58. Form standard 234 is seen in the depiction of Fig. 7 attached to conductive layer 50 of flex circuit 30 with metallic bond 35. Fig. 8 depicts a cross-sectional view of an alternative preferred construction in a contact area in a module 10 in accordance with a preferred embodiment of the invention.

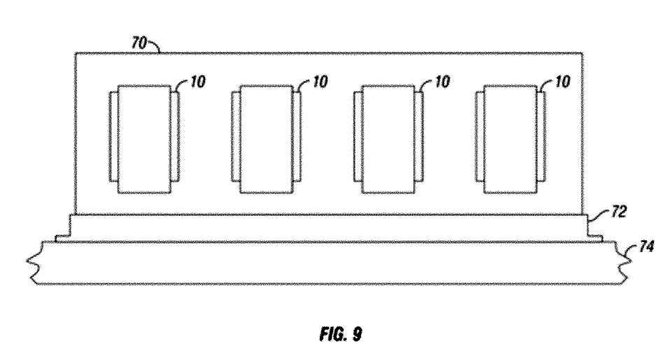

Fig. 9 depicts a series of four 4-high stacked modules 10 mounted on a memory expansion board 70 in accordance with another embodiment of the present invention. As do typical DIMM boards, expansion board 70 shown in Fig. 9 has a set of contacts along one edge that as depicted are set in socket connector 72. Those contacts connect module 10 to a logic system on or connected to board 74 on which expansion board 70 is mounted. It should be understood that in a preferred embodiment of the signaling system provided herein, expansion board 70 will be populated with 8 such modules 10 on a side for a total of 32 devices if the stacked modules are each comprised from four devices, or a total of 64 devices if the DIMM board is populated on both sides. Many other combinations of stack height and number of modules are possible depending on required capacity for the system operating environment. As those of skill will recognize, using four-high stacked modules on expansion board 70 reduces the interconnect length for the number of devices accessed but increase the total number of devices and, therefore, the impedance and particularly, the capacitive loading presented by a densely populated DIMM board.

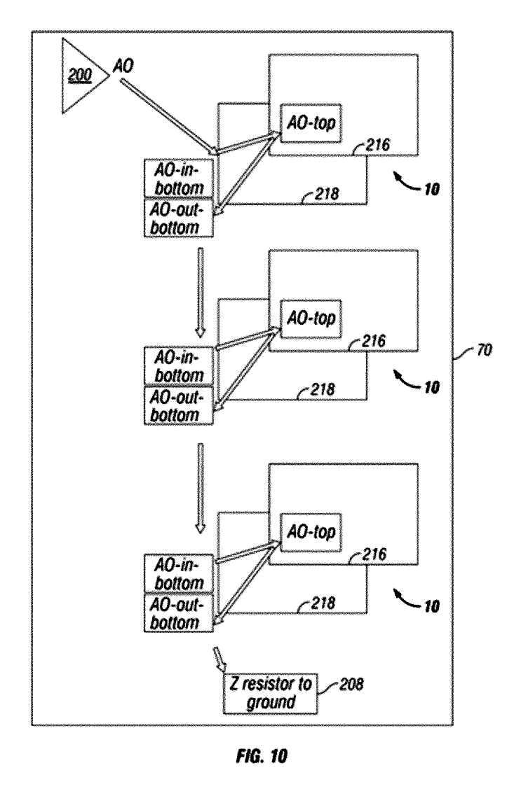

Fig. 10 is a signal flow diagram of a DIMM card according to another embodiment of the present invention. Depicted is a signal interconnection for a single address signal A0 on DIMM board 70 among three iterations of two-high modules 10. Those of skill will understand that multiple address, data, and control lines may be connected in a similar manner, and certain control and data connections will be bi-directionally signaled connections. Memory buffer 200 employs a driver to drive signal A0 through a transmission line to contact A0-in on the bottom CSP 218 of module 10. In this embodiment, a continuous conductive path of flex circuit transmission lines and connections serially connects signal A0 to contact A0 on top CSP 216 and then serially connects to contact A0-out on bottom CSP 218. Depicted are three similarly connected modules 10 being connected in a series by joining contact A0-out of the first module 10 to contact A0-in of the second module and so on. The final module A0-out has a termination resistor 208 connected to ground. Those of skill will realize, after appreciating this specification, that termination resistor 208 may instead be an ODT on the die of CSP 216 or may be, as described with reference to Fig. 2, a combination two ODT terminations. Those of skill will also realize that various signaling schemes having various voltage levels may be employed with the present invention. For example, a current mode signaling scheme having drivers with a high output impedance and receivers with a low output impedance may be employed.

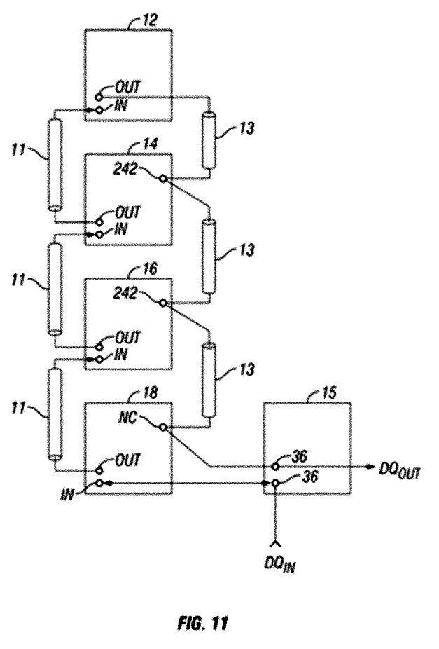

Fig. 11 depicts a stacked IC connection topology according to another embodiment of the present invention. Depicted is the interconnection of one DQ data signal DQ_{IN} through a stack of CSPs having ballouts 12, 14, 16, and 18. Data signal DQ_{IN} connects stack ballout 15 through a module contact 36, which connects module 10 to its operating environment. Module contact 36 is connected to a corresponding DQ contact labeled IN on CSP ballout 18, which CSP ballout is, in this embodiment, the CSP ballout of the lowest CSP in the CSP stack of module 10. Preferably, connection of module contact 36 to contact DQ is made with an inter-contact connection 17 or a trace on a conductive layer of a flex circuit (as described with reference to Figs 5-8). In this embodiment, contact IN is connected to an terminal on CSP 218 which provides one or two-directional signaling capability as well as a capability to re-drive signal DQ onto contact OUT according to a point-to-point inter-IC signaling scheme. Contact OUT is connected to corresponding contacts IN on CSP ballout 16, which receives and re-drives signal DQ in onto the corresponding contact OUT of CSP ballout 16. Each cascade line 11 preferably is connected to the corresponding DQ IN contact at each level through an inter-flex contact 242 (Fig. 5). In this embodiment, cascade lines 11 are composed of the respective conductive layer connections and flex circuit traces described with regard to other-referenced Figures 7 and 8. In this embodiment, contact OUT of CSP ballout 12 is serially connected by cascade line 13 to inter-flex contact 242 associated with CSP ballout 14. In this embodiment, inter-flex contact 242 enables connections between the depicted CSP ballouts according to the scheme depicted in Fig. 5. The lower cascade line 13 connects to contact NC at CSP ballout 18 and to module contact 36 on module ballout pattern 15. In other embodiments, the lower cascade line 13 may not connect to the CSP ballout pattern, but may instead connect directly to a supplemental contact 36E on module ballout pattern 15. The depicted inter-flex contacts 242 are connected to a no-connect (NC) contact on each of the ballouts 14, and 16 (not shown). In other embodiments, inter-flex contact 242 may be provided as a supplemental inter-flex contact which provides a supplemental electrical connection between the stacked layers of module 10. Such supplemental electrical connections may provide a capability to connect any two adjacent stacked layers of module 10 with a number of conductive paths greater than the number of contacts on a particular CSP ballout.

In this embodiment, inter-flex contact 242 on ballout 18 is connected to module contact 36, which connects module 10 to signal DQOUT. In other embodiments, a circuit board trace carrying signal DQOUT may be connected to a corresponding DQIN contact on another module 10, or may be terminated with a transmission line termination. While a data signal DQ is depicted, those of skill will realize that the connection scheme described herein may be used with other signals that have corresponding terminals on multiple CSPs in a stack such as, for example, memory address lines and control lines.

Although the present invention has been described in detail, it will be apparent to those skilled in the art that many embodiments taking a variety of specific forms and reflecting changes, substitutions and alterations can be made without departing from the spirit and scope of the invention. The described embodiments illustrate the scope of the claims but do not restrict the scope of the claims.

What is Claimed is:

1. A high density memory module comprising:
(a) two or more memory CSPs disposed in a stack having a bottom CSP and a top CSP, each CSP having a major surface with a plurality of terminal contacts thereon;
(b) flex circuitry connecting the two or more memory CSPs, a portion of the flex circuitry having module contacts for connecting the module to an operating environment, selected first module contacts being connected to selected ones of the terminal contacts of the bottom CSP, which selected ones being serially connected to corresponding selected ones of the terminal contacts of the remaining memory CSPs in the module, the corresponding selected ones of the terminal contacts of the top CSP having an on-die termination that is kept activated during normal operation of the module.

2. The high density memory module of claim 1 in which the selected ones of the terminal contacts of the bottom CSP have on-die terminations which are deactivated during normal operation of the module.

3. The high density memory module of claim 2 in which the corresponding selected ones of the terminal contacts of any CSPs between the bottom and top CSPs have on-die terminations which are deactivated during normal operation of the module.

4. The high density memory module of claim 1 in which the corresponding selected ones of the terminal contacts of the CSP immediately under the top CSP have on-die terminations which are activated during normal operation of the module.

5. A high density memory module comprising:
(a) two or more memory CSPs disposed in a stack having a bottom CSP and a top CSP, each CSP having a major surface with a plurality of terminal contacts thereon;
(b) flex circuitry connecting the two or more memory CSPs, a portion of the flex circuitry having module contacts for connecting the module to an operating environment, selected first module contacts being connected to selected ones of the terminal contacts of the bottom CSP, which selected ones being serially connected to corresponding selected ones of the terminal contacts of the remaining memory CSPs in the module, the corresponding selected ones of the terminal contacts of the top CSP having a termination resistor mounted on the flex circuitry.

6. A high density memory module comprising:
two or more memory CSPs disposed in a stack having a bottom CSP and a top CSP, each CSP having a major surface with a plurality of terminal contacts thereon; and
flex circuitry connecting the two or more memory CSPs, a portion of the flex circuitry having module contacts for connecting the module to an operating environment, selected first module contacts being connected to selected ones of the terminal contacts of the bottom CSP, which selected ones being serially connected to corresponding selected ones of the terminal contacts of the remaining memory CSPs in the module including the top CSP, corresponding selected ones of the terminal contacts of the top CSP being serially connected to selected second module contacts.

7. A memory expansion board comprising:
(a) a circuit board;
(b) a memory controller having a buffer;
(c) one or more memory modules as claimed in claim 6 mounted on the circuit board, the selected first module contacts of a first one of the one or more memory modules being connected to the memory controller, the one or more memory modules being arranged in an electrical series with any adjacent pairs in the series having their selected first module contacts connected to the selected second module contacts of the previous memory module in the series, if any; and
(d) a memory module as claimed in claim 1 or claim 4 having its selected first module contacts connected to corresponding ones of the selected second module contacts of a final one of the electrical series of the series of memory modules.

8. A memory expansion board comprising:
(a) a circuit board;
(b) a memory controller having a buffer;
(c) one or more memory modules as claimed in claim 6 mounted on the circuit board, the selected second module contacts of a first one of the one or more memory modules being connected to the memory controller, the one or more memory modules being arranged in an electrical series with any adjacent pairs in the series having their selected second module contacts connected to the selected first module contacts of the previous memory module in the adjacent pair, if any; and
(d) a memory module as claimed in claim 1 or claim 4 having its selected first module contacts connected to corresponding ones of the selected first module contacts of a final one of the electrical series of memory modules.

9. A memory expansion board comprising:
(a) a circuit board;
(b) a memory controller having a buffer;
(c) one or more memory modules as claimed in claim 6 mounted on the circuit board, the selected first module contacts of a first one of the one or more memory modules being connected to the memory controller, the one or more memory modules being arranged in an electrical series with any adjacent pairs of modules in the series having their selected first module contacts connected to the selected second module contacts of the previous memory module in the adjacent pair of modules, if any; and
(d) a memory module as claimed in claim 5 having its selected first module contacts connected to corresponding ones of the selected second module contacts of a final one of the electrical series of memory modules.

10. A memory expansion board comprising:
(a) a circuit board;
(b) a memory controller having a buffer;
(c) one or more memory modules as claimed in claim 6 mounted on the circuit board, the selected second module contacts of a first one of the one or more memory modules being connected to the memory controller, the one or more memory modules being arranged in an electrical series with any adjacent pairs in the series having their selected second module contacts connected to the selected first module contacts of the previous memory module in the adjacent pair, if any; and
(d) a memory module as claimed in claim 5 having its selected first module contacts connected to corresponding ones of the selected first module contacts of a final one of the electrical series of memory modules.

11. A memory expansion board comprising:
(a) a circuit board;
(b) a memory controller having a buffer; and
(c) one or more memory modules as claimed in claim 6 mounted on the circuit board, the selected first module contacts of a first one of the one or more memory modules being connected to the memory controller, the one or more memory modules being arranged in an electrical series with any adjacent pairs in the series having their selected first module contacts connected to the selected second module contacts of the previous memory module in the adjacent pair, if any, the selected second module contacts of the final memory module in the electrical series of modules being connected a transmission line termination.

12. The memory expansion board of claim 11 in which there are eight memory modules and in which each of the memory modules comprises a stack of four CSPs.

13. A memory expansion board comprising:
(a) a circuit board;
(b) a memory controller having a buffer; and
(c) one or more memory modules as claimed in claim 6 mounted on the circuit board, the selected second module contacts of a first one of the one or more memory modules being connected to the memory controller, the one or more memory modules being arranged in an electrical series with any adjacent pairs in the series having their selected second module contacts connected to the selected first module contacts of the previous memory module in the pair, if any, the selected first module contacts of the final memory module in the electrical series of modules being connected a transmission line termination.

14. The memory expansion board of claim 13 in which there are eight memory modules and in which each of the memory modules comprises a stack of four CSPs.

15. A method of connecting memory CSPs together to form a system of one or more high density memory modules, the method including the steps:
(a) providing two or more memory CSPs;
(b) connecting the two or more memory CSPs with flex circuits to form one or more stacks each having a plurality of input and output contacts for connection to an operating environment;
(c) serially connecting selected corresponding intermediate terminals on the CSPs in each stack to each other to form a series of connected terminals having a first end and a second end;
(d) serially connecting a selected corresponding input contact on the stack to the first end of the series of connected terminals; and
(e) if the stack is not a final stack in a designated signaling configuration, serially connecting a selected output contact to the second end of the series of connected terminals, and serially connecting the output contact to a corresponding input contact in a next stack in the designated signaling configuration.

16. The method of claim 15 further including the step of, if the stack is a final stack in the designated signaling configuration, connecting a termination at the second end of the series of connected terminals.

17. The method of claim 15 further including the step of programming a memory controller such that during normal operation of the system of one or more high density memory modules, at least one final terminal on a final stack in the designated signaling configuration is operated with an activated on-die termination.

18. The method of claim 17 including the step of programming the memory controller to deactivate on-die terminations for the intermediate terminals.

19. A high density memory module comprising:
(a) a stack of memory CSPs connected with flex circuits, each memory CSP having a plurality of contacts; and
(b) a set of module contacts having a designated one or more input module contacts corresponding to a designated one or more of the contacts on each CSP, the module contacts having a designated one or more output module contacts expressing the same signals as corresponding ones of the one or more input module contacts.

20. The high density memory module of claim 19 in which one or more first contacts on each CSP express a re-driven signal from one or more corresponding second contacts.

21. The high density memory module of claim 20 in which the re-driven signal is a data signal.

22. The high density memory module of claim 20 in which the re-driven signal is an address signal.

23. The high density memory module of claim 20 in which the re-driven signal is a control signal.

24. The high density memory module of claim 19 in which each designated input module contact is serially connected by a continuous conductive path to the corresponding contacts on each CSP and to a corresponding ones of the one or more input module contacts.

25. The high density memory module of claim 19 further comprising two or more form standards, each CSP in the stack having one of the form standards attached to it, the flex circuits being wrapped about selected ones of the form standards.

26. A server having one or more high density memory modules as claimed in claim 1, 4, 5 or 6.

27. A computer system having one or more high density memory modules as claimed in claim 1, 4, 5, or 6.

28. A memory expansion board comprising:
(a) a circuit board;
(b) one or more high density memory modules arranged in a series, each comprising:
(i) a stack of two memory CSPs having a top and a bottom CSP, each of which CSPs having one or more memory integrated circuits each having data terminals and address terminals, the data terminals and address terminals having controllable on-die terminations, the controllable on-die terminations of the data terminals being operated in a deactivated state in normal operation of the circuit board;
(ii) one or more flex circuits electrically connecting the two memory CSPs;
(iii) a plurality of module contacts connecting the one or more high density memory modules to the circuit board, a selected first group of one or more of the module contacts being connected in series to respective ones of the data terminals of the bottom CSP, the respective ones of the data terminals of the bottom CSP being connected in series to respective ones of the data terminals of the top CSP, which data terminals of the top CSP being connected to respective ones of a selected second group of module contacts;
(c) a terminating high density memory module comprising:
(i) a stack of two memory CSPs having a top and a bottom CSP, each of which CSPs having one or more memory integrated circuits each having data terminals and address terminals, the data terminals and address terminals having controllable on-die terminations, the controllable on-die terminations of the data terminals being operated in an activated state in normal operation of the circuit board;
(ii) one or more flex circuits electrically connecting the two memory CSPs;
(iii) a selected first group of one or more of the module contacts being connected in series to respective ones of the data terminals of the bottom CSP, the respective ones of the data terminals of the bottom CSP being connected in series to respective ones of the data terminals of the top CSP;
(d) traces on the circuit board connecting the selected second group of module contacts of each of the high density circuit modules to respective ones in the first group of module contacts of a next module contact in the series; the terminating high density memory module being a final module of the series.

29. A memory expansion board comprising:
(a) a circuit board;
(b) one or more high density memory modules each having a stack of memory CSPs connected with flex circuits, and a set of module contacts connecting a bottom one of the flex circuits to the circuit board, the memory CSPs having a set of data terminals, a set of address terminals, and a set of control terminals, selected ones of which data terminals, address terminals, and control terminals being connected to corresponding data terminals, address terminals, or control terminals of the other CSPs in the stack along a series connection from a selected input module contact, connecting in series to a corresponding selected terminal on each memory CSP in the stack, and connecting in series to a selected output module contact;
(c) a terminating high density memory module having a stack of memory CSPs connected with flex circuits, and a set of module contacts connecting a bottom one of the flex circuits to the circuit board, the memory CSPs having a set of data terminals, a set of address terminals, and a set of control terminals, selected ones of which data terminals, address terminals, and control terminals being connected to corresponding data terminals, address terminals, or control terminals of the other CSPs in the stack along a series connection beginning at a selected input module contact, connecting in series to a corresponding selected terminal on each memory CSP in the stack, the series connection being terminated with a parallel termination;
(d) traces on the circuit board connecting the output module contacts high density memory modules with the input module contacts of a next high density memory module of the one or more memory modules to form a sequence of connections ending with the input module contacts of the terminating high density memory module.

30. The memory expansion board of claim 29 in which the parallel termination is an on-die termination connected to the corresponding selected terminal at the final CSP in the stack.

31. The memory expansion board of claim 29 in which the parallel termination is a resistor connected to the selected terminal at the final CSP in the stack.
